(19) United States
(12) Patent Application Publication
(10) Pub. No.: US 2026/0367130 A1
(43) Pub. Date: Nov. 19, 2026

(54) SYSTEM AND APPARATUS FOR MANAGEMENT OF ELECTRIC GRID

(71) Applicant: Safegrid Oy, Espoo (FI)

(72) Inventors: Tapio MÄNTYSALO, Hevonpää (FI); Klaus OLA, Espoo (FI); Jussi HAKUNTI, Parainen (FI)

(73) Assignee: Safegrid Oy, Espoo (FI)

(21) Appl. No.: 19/126,517

(22) PCT Filed: Apr. 23, 2024
(86) PCT No.: PCT/FI2024/050187

§ 371 Date: May 1, 2025

(30) Foreign Application Priority Data
Apr. 24, 2023 (FI) 20235449

(51) Int. Cl. G01R 31/08

(52) U.S. Cl. CPC G01R 31/086; G01R 31/088

(57) ABSTRACT

A system for managing an electric grid. The system includes a first sensing unit including one or more phase sensors configured to measure values of phase current through each of the one or more phase conductors and a neutral sensor configured to measure value of neutral current through the at least one neutral conductor and a second sensing unit comprising one or more phase sensors configured to measure values of phase current through each of the one or more phase conductors and a second neutral sensor configured to measure value of ground current through the at least one ground conductor and a processing unit operatively coupled with the first sensing unit and the second sensing unit, configured to receive information from the first sensing unit and the second sensing unit to detect a fault event in the electric grid.

### TECHNICAL FIELD

The present disclosure relates generally to grid management, and more specifically, to a system and sensing apparatus for management of an electric grid, including determining network topology, fault detection, and fault location.

### BACKGROUND

Generally, an electric grid comprises power lines, power poles, transformers, switching circuits, protection circuits, and so forth. Such an electric grid may be prone to faults occurring due to lighting, wind, trees falling on lines, apparatus failure, and the like. As an example, the fault may cause over current, under voltage, unbalancing of three phases, high voltage surges, and the like. These faults may cause deviations in voltage values and current values from their nominal ranges in the electric grids. Examples of the faults include, but are not limited to, transient faults, ground faults, earth faults, arcing faults, short circuit faults, open circuit faults, overload faults, broken conductors, lost phases, partial discharges. Most of the faults in the electric grid are transient in nature. In an example, the transient fault may occur due to a tree contact, a bird or an animal contact, a lightning strike, a clash of conductors due to an external force (such as, high wind speed), cracks or impurities in insulation material, and the like.

The management of an electric grid comprises accurately detecting technical faults and errors in the electric grid and/or the electrical components operating therein. However, such an operation is highly complex and cumbersome. Conventionally, existing systems and/or methods aimed at solving the problem attempted to get the switching state information directly from a customer's distribution management system (DMS); however, such an operation is unable to solve the existing problems in an effective manner due to several reasons including, but not limited to, unavailability of customer data in the DMS, customer may not want to share the data, or other challenges in integration in doing this. As a result, a need for a system, apparatus, or method is developed, which can automatically detect the switching states, thereby enabling path selection between the respective sensors and ultimately enabling accurate fault location in all situations.

Furthermore, the management of the electric grids is a highly technical task, for instance due to the high sampling rate producing large amounts of data. In an exemplary scenario of an event recorder employed for monitoring the electric grid, at a sampling rate of 1 Mega Hertz (MHz), a corresponding recording for a duration of one second (s) produces 2 megabytes (MB) of data, when sampled with either 12 bits or 16 bits i.e., 2 bytes per sample. In the current exemplary scenario, a recording of a duration of 5 s per hour, would produce 240 MB data in 24 hours, and correspondingly 87.6 gigabytes (GB) data from a single event recorder annually. Therefore, using conventional techniques for management of an electrical utility network comprising 1000 transient recording devices, 87.6 Terabytes (TB) of data would approximately be produced annually. Such conventional implementation for management of the electric grid produces a lot of data and thus increases the computational requirements for the management of the electric grids. Consequently, such implementation would be very expensive especially in case the data is to be transmitted over a longer distance and/or to be stored/recorded e.g., for analysis purposes.

Therefore, in light of the foregoing discussion, there exists a need for a system and/or an apparatus for management of electric grids which can addresses and/or alleviates above discussed problems; and can automatically and accurately detect and locate fault in all types of situations (or networks) and can reduce the computational power and memory requirements to do so in an efficient and cost-effective manner.

### SUMMARY

An object of the present disclosure is to provide a system for management of an electric grid. Another object of the present disclosure is to provide an apparatus for executing the system for management of the electric grid. Yet another object of the present disclosure is to provide a solution that overcomes at least partially the problems encountered in the prior art.

In an aspect, an embodiment of the present disclosure provides a system for management of an electric grid, the electric grid comprising a plurality of distribution lines having one or more phase conductors, at least one ground conductor and/or at least one neutral conductor, the system comprising:
a first sensing unit comprising:
   one or more phase sensors configured to measure values of phase current through each of the one or more phase conductors; and
   a neutral sensor configured to measure value of neutral current through the at least one neutral conductor;
a second sensing unit comprising:
   one or more phase sensors configured to measure values of phase current through each of the one or more phase conductors; and
   a second neutral sensor configured to measure value of ground current through the at least one ground conductor; and
a processing unit operatively coupled with the first sensing unit and the second sensing unit; the processing unit configured to:
   receive information about measurements of currents from the first sensing unit and the second sensing unit;
   determine changes in values of current measured through each of the one or more phase conductors and the value of neutral current measured through the at least one neutral conductor via the first sensing unit and changes in values of current measured through each of the one or more phase conductors and the value of ground current measured through the at least one ground conductor via the second sensing unit; and
   detect a fault event thereof in the electric grid based on the determined changes in values of currents from the first sensing unit and the second sensing unit.

In another aspect, the present disclosure provides a sensing apparatus comprising:
a first sensing unit comprising:
   one or more phase sensors configured to measure values of phase current through each of the one or more phase conductors; and
   a neutral sensor configured to measure values of neutral current through the at least one neutral conductor; and
a second sensing unit comprising:
   one or more phase sensors configured to measure values of phase current through each of the one or more phase conductors; and
   a second neutral sensor configured to measure values of ground current through the at least one ground conductor.

Embodiments of the present disclosure substantially eliminate or at least partially address the aforementioned problems in the prior art and enable efficient and effective management of the electric grid via the system.

### BRIEF DESCRIPTION OF DRAWINGS

Embodiments of the present disclosure will now be described, by way of example only, with reference to the following diagrams wherein:

FIG. 1 is a block diagram of a system for management of an electric grid, in accordance with one or more embodiments of the present disclosure;

FIG. 2 is a block diagram of a sensing apparatus, in accordance with one or more embodiments of the present disclosure;

FIGS. 3A and 3B are exemplary depictions of electric pole(s) implemented for carrying a plurality of distribution lines, at least one neutral conductor and at least one ground conductor of the electric grid, in accordance with one or more embodiments of the present disclosure;

FIG. 4 is a simplified electric grid depicting working of a first sensing unit, in accordance with one or more embodiments of the present disclosure;

FIG. 5 is a schematic diagram of a portion of an electric grid managed via the system of FIG. 1, in accordance with one or more embodiments of the present disclosure;

FIGS. 6A and 6B are exemplary scenarios of implementation of the first sensing unit and a second sensing unit, respectively, in the electric grid of FIG. 5, in accordance with one or more embodiments of the present disclosure;

FIG. 7 is an exemplary working environment of the system of FIG. 1, in accordance with one or more embodiments of the present disclosure;

FIGS. 8A to 8C are schematic diagrams depicting implementations of the first sensing unit in different electrical grids having at least one neutral conductor, in accordance with one or more embodiments of the present disclosure;

FIG. 8D is an exemplary illustration of a measurement configuration of a system, in accordance with an embodiment of the present disclosure; and

FIG. 9 is a schematic diagram depicting implementation of the second sensing unit in an exemplary three-phase compensated with at least one ground conductor, in accordance with one or more embodiments of the present disclosure.

### DETAILED DESCRIPTION OF EMBODIMENTS

The following detailed description illustrates embodiments of the present disclosure and ways in which they can be implemented. Although some modes of carrying out the present disclosure have been disclosed, those skilled in the art would recognize that other embodiments for carrying out or practicing the present disclosure are also possible.

The present disclosure provides a system for management of an electric grid. The term “electric grid” as used herein refers to a type of interconnected electrical network configured to deliver electricity to (or from) the connected elements therein via the plurality of associated distribution lines (also called feeder or transmission lines). The electric grid is configured to operate between a set of the electrical components such as, switching devices, transient event recorders, current sensors, voltage sensors, electrical stations, and other electrical and/or electronic elements operating within the electric grid. The electric grid is a part of an electrical grid network which distributes electrical power from distribution substation(s) to premises (such as homes, offices, factories, and the like) of consumers. The electric grid comprises distribution or power lines, electric poles, transformers, switching circuits, protection circuits, and so forth. The electrical distribution lines (or overhead lines) refer to one or more uninsulated electrical cables suspended by the electric pole, for electric power transmission and distribution to transmit electrical energy across large distances. The electrical distribution lines transmit electricity of high voltages, which when interacted with, may cause damage. Optionally, the distribution lines are made of a plurality of wires of conducting material wrapped in a non-conductive and non-corrosive material. For example, a plurality of metal wires wrapped in plastic. Moreover, each electrical distribution line comprises a plurality of wires. Herein, the wires are twisted together to form the distribution line. In an example, the electrical distribution line may have three wires.

In the present embodiments, the electric grid comprising a plurality of distribution lines, at least one ground conductor and at least one neutral conductor. Typically, the plurality of distribution lines is configured for distributing power or electricity (for example, 3-phase), wherein the at least one ground conductor acts as a low resistance path for fault current to flow to the ground and the at least one neutral conductor acts as a return path for current to flow from load (i.e., equipment) to source (transformer). Beneficially, monitoring of the plurality of distribution lines, the at least one ground conductor and the at least one neutral conductor allows the system to identify and locate any faults occurring within any part of the electric grid and completely manage the entire electric grid as explained further in detail in the present disclosure. It will be appreciated that the system may be configured to monitor and manage other parts of the electric grid apart from the aforementioned for effective management thereof without any limitations.

In other embodiments, the system may also comprise a 1-phase, or a 2-phase system. For example, a distribution line (A) of the plurality of distribution lines may have a 1-phase system, having a single 1-phase conductor, and another feeder (B), may have a 3-phase, or a 2-phase system, or both. Alternatively stated, the system may comprise different types of feeders or distribution lines, i.e., a 1-phase system having a single-phase conductor, and/or a 2-phase system having two phase conductors, and/or a 3-phase system having three phase conductors and thereby not limited to 3-phase systems.

However, as discussed, the electric grid is prone to faults occurring due to lighting, wind, trees falling on lines, apparatus failure, and the like. As an example, the fault may cause over current, under voltage, unbalancing of three phases, high voltage surges, and the like. These faults cause deviations in voltage values and current values from their nominal ranges in the electric grids. Examples of the faults include, but are not limited to, transient faults, earth faults, arcing faults, short circuit faults, open circuit faults, overload faults. Most of the faults in the electric grid are transient in nature. In an example, the transient fault may occur due to a tree contact, a bird or an animal contact, a lightning strike, a clash of conductors due to an external force (such as, high wind speed), and the like. Thus, the monitoring of such fault events as discussed in the present disclosure becomes a highly data consuming task and thus, correspondingly increases the computational power and memory requirements of the monitoring system.

In the present embodiments, the system comprises a first sensing unit and a second sensing unit. Herein, in some embodiments, the first sensing unit and the second sensing unit may be arranged at a distance from each other in separate enclosures. Alternatively, the first sensing unit and the second sensing unit may be arranged remotely i.e., at a distance from each other in separate enclosures to eliminate any potential interferences to ensure fault free operation of the electric grid. The distance between the second sensing unit and the first sensing unit may be varied based on the requirements of the system. In an example, the system comprises the second sensing unit, which is arranged, e.g., in a substation, and the first sensing unit which is arranged at the electric pole(s). Beneficially, such an arrangement enables the system to eliminate measurement errors to improve monitoring accuracy. Additionally, based on location information such as, of the electric pole, the first sensing unit, the second sensing unit, the system may detect and locate the fault in the electric grid. Notably, the first sensing unit is located at a predefined distance from the second sensing unit, which may be in a substation, and that there can be one or more electric (or utility) poles along the line between the first sensing unit and the second sensing unit. Notably, the number of sensing units is not limited.

Throughout the present disclosure, the term “sensing unit” refers to a structure and/or module (such as, an electro-mechanical arrangement or device or integrated circuit configured refers to) that includes programmable and/or non-programmable components configured to store, process and/or share information and/or signals for detecting or sensing a specific physical parameter and converting it to an electrical signal. The output signal of the sensing unit is processed and used to provide a measurement or to trigger a corresponding action. For example, the sensing unit may be configured to sense or detect at least the presence and magnitude of at least one of an electric field, or a magnetic field, or an electromagnetic field. The sensing unit comprises a plurality of sensors or sensor devices, that generate sensor data for a magnetic field in each dimension. Moreover, the sensing unit generates the sensor data based on the sensed presence and magnitude of the associated electric or magnetic field. It will be appreciated that any types of sensor may be employed in the sensing unit that may aid in the management of the electric grid may be employed by the system, but not limited to, phase sensors (CTs), voltage transformers (VTs), phasor measurement units (PMUs), merging units (MUs), smart meters, temperature sensors, humidity sensors, accelerometers, rain gauges, internet protocol (IP) network cameras, pyranometers and pyrheliometers (solar irradiance) and so forth. Typically, the sensing unit is configured to sense or measure voltages and/or currents flowing through the plurality of distribution lines, the at least one neutral conductor, and the at least one ground conductor of the electric grid. The sensing unit comprises one or more sensor devices or equipment. Optionally, the sensing unit is an analog sensing unit. Alternatively, optionally, the sensing unit is a digital sensing unit. Examples of sensing equipment of the measurement unit include, but are not limited to, a voltmeter, an ammeter, a multimeter, and other sensory devices. Herein, the sensing unit is configured to monitor a signal of electromagnetic field, electric field, and/or magnetic field of at least one of said plurality of transmission lines or distribution lines associated to the electric grid, detect a transient event signal in the monitored signal, corresponding to a fault event in the electric grid. Moreover, the sensing unit is operable to perform one or more operations for sensing or collecting information relating to the measurements of the current and thereby transmitting them to any other computation device upon requirement. Optionally, the sensing unit includes any arrangement of physical or virtual computational entities capable of enhancing information to perform various computational tasks. In the present examples, the sensing unit may include components such as memory, a processor, a network adapter, and the like, to store, process and/or share information with other computing components, such as a user device, a remote server unit, a database arrangement. Additionally, the sensing unit is arranged in various architectures for responding to and processing the instructions for management of the electric grid via the system.

Throughout the present disclosure, the term “sensor” refers to a device which senses the presence and magnitude of a magnetic field in a given plane. Moreover, the sensor generates the sensor data based on the sensed presence and magnitude of the magnetic field. Optionally, a given sensor comprises a phase sensor and a measurement apparatus (or a processing unit) arranged in a circuit including the phase sensor. Herein, the measurement apparatus, in operation, measures an induced current in the circuit, the sensor data comprising values of the induced current in the circuit. Further, the sensor data may be processed to generate the measurement data, to determine values of magnetic field densities produced by electrical current in the plurality of distribution lines and determine the values of currents flowing through the plurality of distribution lines, based on the values of the magnetic field densities measured by the sensors and the directivity and orientation of the sensors and distance and position of the plurality of distribution lines from the sensors. Optionally, the sensor further comprises an anti-disturbance filter, an amplifier, a digitizer, an optical transmitter and/or a radio transmitter. Beneficially, this helps to reduce disturbances during measurement of the magnetic fields via the system, and to reduce disturbances during measurement of the magnetic fields and/or to improve voltage isolation from high-voltage components.

As mentioned, in the present embodiments, the system comprises the first sensing unit. Herein, the first sensing unit comprises one or more phase sensors configured to measure values of phase current through each of the plurality of distribution lines and a neutral sensor configured to measure values of neutral current through the at least one neutral conductor. The term “phase sensor” as used herein refers to a type of magnetic field sensor configured to measure values of magnetic field intensity generated due to the phase current flowing through each of the plurality of distribution lines. For example, the phase sensor may be at least one of a Rogowski coil, or a ferrite sensor, or a Peterson coil. Optionally, the phase sensor detects an electromechanical field. Moreover, the associated sensing unit measures a value of the magnetic field sensed by the phase sensor, by way of measuring an induced current in the circuit. In operation, the phase sensor senses a magnetic field, which is measured by the associated first sensing unit or the second sensing unit. The induced current refers to current being induced in the circuit, due to the magnetic field caused by the voltage transmitting through the distribution lines.

In one or more embodiments, one of the one or more phase sensors in the first sensing unit is connected to one of the one or more phase conductors in the plurality of distribution lines of the electric grid. In an example, if the distribution lines are configured for supplying a 3-phase power via three single phase conductors, the system correspondingly comprises three phase sensors for measuring values of phase current through each of the three phase conductors of the plurality of distribution lines. In another example, if the plurality of distribution lines is configured for supplying a 1-phase power via one single phase conductor, then, in the first sensing unit, one phase sensor is arranged to measure the phase current in the single-phase conductor. Correspondingly, if the plurality of distribution lines is configured for supplying a 2-phase power, having one 1-phase conductor (L1) and one 2-phase conductor (L2) and a neutral conductor, then two phase sensors are arranged to measure the currents in the phase conductors (L1, L2), i.e., one phase sensor per each phase conductor.

In some examples, the phase sensor is implemented as a coil wound around a ferrite core, wherein the coil is made of a conducting material. Optionally, the conducting material is implemented as at least one of: copper, gold, silver, aluminum. Herein, the term “ferrite” refers to a ceramic material made by iron (III) oxide and at least one additional metallic element. Optionally, the additional metallic element is implemented as at least one of: strontium, barium, manganese, nickel, zinc. It will be appreciated that the ceramic material is ferrimagnetic, meaning thereby, that the ferrite core is magnetizable and/or be attracted to a magnet. Optionally, the ferrite core is made by heating the ceramic material and molding it into a cylindrical shape. Optionally, the coil is made by stretching bits of the conducting material to form a wire. Optionally, a resonant frequency of the coil is higher than a Nyquist frequency of an input sampling frequency of an analog front end of the electrical utility grid. A technical effect of this is that this configuration guarantees high gain in high frequencies, which in turn is beneficial for accurate detection of the current transient.

The term “magnetic field density” refers to the amount of magnetic force induced in the circuit due to the magnetisation caused by current being transmitted through the plurality of distribution lines, or the at least one neutral conductor, or the at least one ground conductor. It will be appreciated that the magnetic field density of a given distribution line is utilized to determine the value of current flowing through the given distribution line. Optionally, the value of current flowing through the given distribution line is determined using formulae. Herein, the distance of the sensing unit from the distribution line on the x axis is Lₓ, the distance of the sensing apparatus from the distribution line on the y axis is L_{y}, and the approximate distance of the sensing apparatus from the distribution line is L_{xy}.

In present examples, sensor signals of a given sensor are mathematically represented as:

$${H}_{m} = \sum {l}_{n} * {D}_{m , n} / {L}_{m , n} .$$

$$( \begin{matrix}{H}_{x} \\ {H}_{y} \\ {H}_{z}\end{matrix} ) = ( \begin{matrix}{A}_{xa} & {A}_{xb} & {A}_{xc} \\ {A}_{ya} & {A}_{yb} & {A}_{yc} \\ {A}_{za} & {A}_{zb} & {A}_{zc}\end{matrix} ) ( \begin{matrix}{I}_{a} \\ {I}_{b} \\ {I}_{c}\end{matrix} )$$

$$such that ,$$

$${A}_{mn} = {D}_{mn} / {L}_{n} .$$

wherein:
H=magnetic field detected
m=given sensor device (x, y, z)
n=index number of a wire of the distribution line (a, b, c)
I=current in the wire of the distribution line
D=directional gain of the sensor to the wire of the distribution line; and
L=distance between the sensor and the wire of the distribution line.

The line currents of each of the three phase conductors of one of the plurality of distribution lines can be calculated using the matrix equation above, when D and L of each conductor/sensor pair are known. A technical effect of this is that the use of phase sensors avoids direct connection of the associated sensing unit with the distribution lines, which, in turn, makes the associated sensing unit economical, and simultaneously allowing the system to be utilized with pre-existing electrical utility grids as well. Moreover, the first sensing unit or the second sensing unit can be hot-installed (i.e., installed without turning the system off) behind safety distance, and also there is no cost for safety insulation between the mid- or high-voltage line and the associated sensing unit.

In an embodiment, the phase sensor is implemented as an air-core coil. The term “air-core coil” refers to a coil wound around a non-magnetic core. Optionally, the air-core coil may be wound around a plastic, a ceramic, a glass, a chunk of fabric, a piece of wood, or even air. A technical advantage of this is that it is cheaper, is free from iron losses, resulting in less distortion.

In an alternative embodiment, the phase sensor is implemented as a hall-effect sensor. The term “hall-effect sensor” refers to a sensor which detects the presence and magnitude of a magnetic field using the Hall effect. In operation, the hall-effect sensor distinguishes between the positive and negative charge moving in opposite directions. Moreover, a magnetic field detected by the hall-effect sensor is converted to suitable analog or digital signals which can be read by the measurement device. Optionally, the hall-effect sensor is made using at least one of: gallium arsenide (GaAs), indium arsenide (InAs), indium phosphide (InP), indium antimonide (InSb), graphene. A technical advantage of this is that hall-effect sensors have reduced wear and tear due to absence of moving parts, which substantially reduces the maintenance costs.

In another alternative embodiment, the phase sensor is implemented as a metal core sensor. The term “metal core sensor” refers to a phase sensor having a metallic core and wound with fiber or ceramic coil. Optionally, the metal core sensor is an iron core sensor. A technical advantage of this is faster travel speeds and higher deposition rates, resulting in increased efficiency and reduced costs.

However, merely monitoring the plurality of distribution lines often limits the management capability of conventional electric grid management systems, since faults or errors may occur in different parts of the electric grid. Thus, to effectively and completely monitor and manage the electric grid, the first sensing unit further comprises a neutral sensor, configured to measure values of neutral current through the at least one neutral conductor. The term “neutral sensor” refers to a type of sensor configured to measure values of neutral current flowing through the at least one neutral conductor in the electric grid. For example, the neutral sensor may be one of a ferrite sensor, a current transformer or a Rogowski coil, a Peterson coil, etc. The neutral sensor may be a magnetic sensor that may be configured to measure magnetic field intensity of the at least one neutral conductor owed due to the flowing neutral current. To effectively monitor the electric grid, the system comprises the first sensing unit configured to measure phase currents flowing through the plurality of distribution lines and neutral current flowing through the at least one neutral conductor in the electric grid. In an exemplary scenario of an electric pole having three phase wires for carrying load (i.e., the plurality of distribution lines), and a neutral wire (i.e., the at least one neutral conductor) for completing the circuit, the first sensing unit may be configured to measure the phase currents through each of the three phase conductors and the neutral conductor and thereby transmit the sensed or measured information for further processing to enable the system to detect any faults or errors in the neutral conductors or the distribution lines for enabling complete and effective management of the electric grid via the system.

Further, as mentioned, the system comprises the second sensing unit. Herein, the second sensing unit comprises one or more phase sensors configured to measure values of phase current through each of the plurality of distribution lines, and a second neutral sensor configured to measure values of ground current through the at least one ground conductor. To effectively monitor the electric grid, the second sensing unit is configured to measure ground current flowing through the at least one ground conductor and phase currents through the one or more phase conductors of the plurality of distribution lines in the electric grid. In an exemplary scenario of an electric grid, the second sensing unit is installed near or at a power substation, wherein the one or more phase sensors of the second sensing unit are connected to the one or more phase conductors configured for carrying load (i.e., the plurality of distribution lines) from the substation, and to a ground conductor associated with the substation. The second sensing unit may be configured to measure the phase currents through each of the one or more phase conductors and the ground conductor and thereby transmit the sensed or measured information for further processing to enable the system to detect any faults or errors in the ground conductors or the one or more phase conductors or the plurality of distribution lines for enabling complete and effective management of the electric grid via the system. In an exemplary scenario, if there is any fault event within the electric grid, e.g., if a tree falls or leans against the phase conductor, the first sensing units which are near the fault location sense a lower current than the second sensing unit i.e., installed at the substation, which senses the entire sum current (which may be higher). Correspondingly, such an implementation enables the system to effectively determine any or all types of fault events in the electric grid for enabling efficient repair and management.

In an embodiment, in the second sensing unit, each of the one or more phase sensors and the second neutral sensor is one of a Rogowski coil sensor, a current transformer or a magnetic sensor. In another embodiment, in the second sensing unit, each of the one or more phase sensors is a magnetic sensor and the second neutral sensor is a Rogowski coil sensor or a current transformer.

In an embodiment, in the first sensing unit, each of the one or more phase sensors and the neutral sensor is one of a Rogowski coil sensor, a current transformer or a magnetic sensor. In another embodiment, in the first sensing unit, each of the one or more phase sensors are magnetic sensors and the neutral sensor is a Rogowski coil sensor.

In an alternative embodiment, in the first sensing unit and/or the second sensing unit, at least one of the one or more phase sensors, the at least one neutral sensor, or the at least one second neutral sensor, is implemented as an arc suppression coil. The arc suppression coil (also referred to as Peterson coil or earth fault neutraliser) is configured for compensation of capacitive currents during earth faults in the electric grid. Beneficially, the implementation of the arc suppression coil eliminates the need for multiple or different sensors and at the same time enables accurate measurement of neutral and/or ground currents from high impedance ground faults.

The system further comprises a processing unit operatively coupled with the first sensing unit and the second sensing unit. The term “processing unit” as used herein refers to a structure and/or module that includes programmable and/or non-programmable components configured to store, process and/or share information and/or signals for management of the electric grid. The processing unit may have elements, such as a display, control buttons or joysticks, processor, memory, and the like. Typically, the processing unit is operable to perform one or more operations for managing the electric grid. Optionally, the processing unit includes any arrangement of physical or virtual computational entities capable of enhancing information to perform various computational tasks. Optionally, the processing unit is supplemented with additional computation systems, such as neural networks, and hierarchical clusters of pseudo-analog variable state machines implementing artificial intelligence algorithms. In the present examples, the processing unit may include components such as memory, a controller, a network adapter, and the like, to store, process and/or share information with other components, such as a current sensor, a voltage sensor, a remote server unit, a database. Optionally, the processing unit is implemented as a computer program that provides various services (such as database service) to other devices, modules, or apparatus. The processing unit is communicably coupled to the second sensing unit and the first sensing unit wirelessly and/or in a wired manner. In an example, the processing unit may be implemented as a programmable digital signal processor (DSP). In another example, the processor may be implemented via a cloud server that provides a cloud computing service. In some implementations, the processor is integrated with the second sensing unit and the first sensing unit. In such implementations, the processing unit is physically coupled to the second sensing unit and/or the first sensing unit (for example, attached via mechanical and electrical connections). In other implementations, the processing unit is implemented separately from the first sensing unit and the second sensing unit. Optionally, the processing unit is communicably coupled to a data repository. It will be appreciated that processed data is stored at the data repository. The data repository is optionally implemented as a memory. The memory may be local memory that is integrated with the processing unit, or an external memory, or a cloud-based memory, or similar.

Additionally, the processing unit is arranged in various architectures for responding to and processing the instructions for management of the electric grid via the system. Herein, the system elements may communicate with each other using a communication interface. The communication interface includes a medium (e.g., a communication channel) through which the system components communicate with each other. Examples of the communication interface include, but are not limited to, a communication channel in a computer cluster, a Local Area Communication channel (LAN), a cellular communication channel, a wireless sensor communication channel (WSN), a cloud communication channel, a Metropolitan Area Communication channel (MAN), and/or the Internet. Optionally, the communication interface comprises one or more of a wired connection, a wireless network, cellular networks such as 2G, 3G, 4G, 5G mobile networks, and a Zigbee connection.

The processing unit is configured to receive information about measurements of currents from the first sensing unit and the second sensing unit. Generally, the system is configured to monitor a signal of electromagnetic field, electric field, and/or magnetic field of at least one of said plurality of distribution lines, the at least one neutral conductor, and the at least one ground conductor associated to the electric grid. Further, based on the monitored signal during different instants of time, the processing unit may further determine (or detect) any changes in the received measurements of currents from the first sensing unit and/or the second sensing unit, wherein the detected changes are indicative of a fault or error occurring in the electric grid. Herein, the system is configured to monitor the current, voltage, electromagnetic signals, the electric signals, or the magnetic signals emanating from at least one of the pluralities of transmission or distribution lines of the electric grid via the first sensing unit and/or second sensing unit. The system is configured for monitoring operation of the electric grid via measuring of, for example, but not limited to, the current levels, the voltage levels, the electric field strength, the magnetic field strength, the power, and the like. Such monitoring operation encompassing each of the electromagnetic signals, the electric signals, the magnetic signals, enables the system to effectively analyze the electric grid and thereby detect any faults or errors occurring in the electrical grid from analysis thereof.

That said, problems may persist during measurement and/or monitoring of data as encountered by conventional solutions. For example, during measurement of the at least one neutral wire via a first sensing unit, if a tree happens to fall on the distribution line with the tree leaning against the line, it will ground the phase to the ground and not to the at least one neutral wire that the first sensing unit is measuring, and thus, no change no change in current values is detected by the first sensing unit. Consequently, conventional solutions are unable to detect earth faults. However, in the present embodiments, since the first sensing unit or the second sensing unit are located near a substation and may be configured to measure the values of current in the at least one neutral wire, the corresponding sensing unit may observe and thereby detect the change in current that a tree falling on the line would cause and correspondingly, based on the current difference, determination of an earth fault may take place.

The processing unit is further configured to determine changes in values of current through each of the one or more phase conductors and the at least one neutral conductor via the first sensing unit and/or changes in values of current through each of the one or more phase conductors and the at least one ground conductor via the second sensing unit and detect a fault event and location thereof in the electric grid based on the determined changes in values of current from corresponding second sensing unit or the first sensing unit. Typically, the processing unit is configured to process the sensor data received from the first sensing unit and the second sensing unit and thereby determine or detect any and all changes in values of current in the plurality of distribution lines, or the at least one neutral conductor, or the at least one ground conductor. Correspondingly, based on a detected change in values of current from corresponding second sensing unit or the first sensing unit, the processing unit is further configured to detect the fault event and location thereof based on the observed changes. The detection of a fault event is based on comparison of changes between the values measured by the first sensing unit and the values measured by the second sensing unit.

A typical signal processing sequence may be an event, for example a short-circuit or an earth fault, or a ground fault, occurring in a distribution line, emitting transient signals that travel close to light speed on the distribution line. Herein, the sensing unit arranged at a location on the said distribution line may be configured to detect the transient signal and convert part of the signal into an electrical signal that may be further processed by electronic devices. Throughout the present disclosure, the term “fault event” refers to a type of fault occurring in the electric grid. For example, the fault event may be a ground fault occurring due to a collapsed tree on any of the plurality of distribution lines, or an earth fault caused due to damaged insulation, or a transient fault event (i.e., short-lived burst of energy), and the like. Optionally, the fault events comprise transient fault signals that are non-stationary-type of signals. The fault transients die very quickly by itself, but when the fault transient is detected repeatedly in the electric grid, it strains network of the electric grid, weakens isolation capability of the electric grid at a location (namely, a site) of fault occurrence, and may lead to permanent disturbance and/or failure in electrical assets of the electric grid. Therefore, for a smooth operability of the electric grid, the fault transients are efficiently detected using the present system to identify a fault event occurrence so that required repairs can be made before a permanent failure. Herein, the fault events may be obtained from measurements of voltages and/or currents at distribution substations in the electric grid. Generally, for the purpose of detecting the fault events, in some distribution substations, phase voltages and the phase current are recorded, while in other distribution substations phase voltages and phase currents are recorded.

Notably, the system is enabled to detect earth or ground faults from load changes occurring within the electric grid. In an exemplary scenario, if there is an external load, e.g., a kind of machine, or connection of additional feeder lines to the grid, which draws more current at the line, then such an increase in current consumption can be observed in the at least one neutral conductor via the neutral sensors. Typically, the neutral sensors of the first sensing unit are arranged along the plurality of distribution lines to detect such current changes simultaneously. As a result, the system determines such current changes due to a given change in load. Consequently, if the current on the neutral conductor increases only at the substation, or at the transformer, but the change in current consumption is not detected in the neutral wire further down on outgoing line, then such an event is characterized as a ground fault. For example, a tree, or any object, leaning against any given phase conductor. If there is a current increase on any of the ground wires monitored, without corresponding increase in the neutral wire currents, then also that is an indication of a ground fault.

In other words, if the neutral sensors detect the increase in current consumption in the same way, i.e., the current measured by the neutral sensors is in the same predetermined range, and/or the values they provide, based on sensing, are of the same order of magnitude in the neutral sensors, then the event is not characterized as a fault. If, however, there are differences detected in the measurement values by the neutral sensors, for example a higher value, or a value which is above a predetermined threshold value, is detected at the substation, or at the transformer, than in the outgoing phase conductors, then the event is characterized as a fault.

In one or more embodiments, the processing unit is configured to detect the fault locations based on corresponding changes in values of current in the at least one neutral conductor or the at least one ground conductor, respectively. Beneficially, any faults occurring within the system are uniquely localized for control via the system and thereby enabling appropriate remediation in an efficient manner via the system.

In one or more embodiments, the processing unit is further configured to process the information about measurements of currents from the first sensing unit and the second sensing unit, and wherein the information about measurements of currents comprises values of at least one of: phase currents through each of the plurality of distribution lines, ground current through the at least one ground conductor, or neutral current in the at least one neutral conductor, to determine changes in values of current through each of the plurality of distribution lines, the at least one neutral conductor, or the at least one ground conductor. Typically, the information processed via the processing unit comprises measurements of phase currents through each of the plurality of distribution lines, the ground current through the at least one ground conductor, and the neutral current through the at least one neutral conductor, wherein processing the information enables detection of changes in measurements of the phase currents, the neutral current, and the ground current that are indicative of the transient fault events in the electric grid. Such an implementation enables the processing unit or the system to uniquely identify any and all faults occurring within the electric grid and simultaneously allowing localization of said faults in the electric grid for effective management thereof via the system.

In one or more embodiments, the phase currents are determined based on measured voltages via formulas:
first voltage V1=M(i1′(t));
second voltage V2=M(i1′(t)+i2′(t)); and
third voltage V3=M(i1′(t)+i2′(t)+i3′(t)),

wherein M is the mutual inductance of each of the one or more phase sensors in the second sensing unit or the first sensing unit.

Herein, “i1′(t)” is a derivative of phase current of the first phase, “i2′(t)” is a derivative of phase current of the second phase, and “i3′(t)” is a derivative of phase current of the third phase. Notably, “i1(t)” is the phase current of the first phase, “i2(t)” is the phase current of the second phase, and “i3(t)” is the phase current of the third phase. Hereinafter, “i1(t)” is referred to as “first phase current”, “i2(t)” is referred to as “second phase current”, and “i3(t)” is referred to as “third phase current”, for the sake of convenience only.

The above formulas enable in determining the derivatives of the first phase current, the second phase current, and the third phase current. A sum of these derivatives may be integrated to calculate the phase current. The phase current is a sum of the first phase current, the second phase current, and the third phase current. In this regard, the phase current is mathematically expressed as i1(t)+i2(t)+i3(t), and its derivative is given by measurement of the third voltage. It is to be noted that the phase current is a function of time, which means that the magnitude of the phase current may be different at different time instants. It will be appreciated that a range of the third voltage signal is dimensioned based on a magnitude of maximum phase current and is independent of magnitude of the load currents. In this regard, beneficially, the measurement of the third voltage signal achieves a high-resolution. Also, it may be noted that, herein, the mutual inductance of all the three phase sensors is assumed to be equal.

In one or more embodiments, the phase currents are determined for each phase of the plurality of distribution lines via formulas:
first phase i1′(t)=v1(t)/M;
second phase i2′(t)=(v2(t)−v1(t))/M; and
third phase i3′(t)=(v3(t)−v2(t))/M,

wherein M is the mutual inductance of each of the one or more phase sensors in the second sensing unit or the first sensing unit.

Optionally, the phase currents are calculated with following formulas:
for the first phase i1′(t)=v1(t)/M,
for the second phase i2′(t)=(v2(t)−v1(t))/M,
for the third phase i3′(t)=(v3(t)−v2(t))/M,

wherein M is the mutual inductance of the phase sensors.

Herein, the measured first voltage, second voltage, and third voltage are represented as function of time v1(t), v2(t), and v3(t), respectively. In such a case, the derivatives of phase currents can be calculated as functions of time, and the phase currents can be calculated by integrating the derivatives of phase currents. It will be appreciated that, optionally, an inverse transform is employed for calculating the actual phase currents from the measured first voltage, second voltage and third voltage. It will also be appreciated that using the measured first voltage, second voltage, third voltage, and the calculated phase current enable accurate measurements of phase currents.

In one or more embodiments, when determining the values of currents flowing through the one or more phase conductors, the processing unit, or the first or second sensing unit, is further configured to subtract from the values of magnetic field densities measured for the one or more phase conductors the values of magnetic field densities measured for the neutral conductor and/or the ground conductor to reduce disturbances during measurement of the magnetic fields of the phase conductors. The currents on a neutral conductor traveling under the one or phase sensors which measure the phase currents from a safe distance, will disturb the phase current measurements. The one or more phase sensors measuring the phase currents from a distance do measure also the magnetic fields generated by the currents in neutral (or ground) conductors. The phase conductor current measurements can be restored to measuring only the phase currents by accurately measuring the neutral (or ground) conductor current, calculating the magnetic field generated by this neutral (or ground) conductor, then mathematically subtracting this magnetic field from each of the magnetic field sensors. The magnetic sensor sensitivity and directivity, the magnetic sensor installation location in respect to the phase and neutral (ground) conductors and direction in 3D or at least 2D space, and the neutral (or ground) conductor generated magnetic field strength and direction at that location must all be calculated and using the earlier mentioned matrix formula, first subtracting the neutral (ground) conductor induced magnetic field, this will yield the original phase current measurements.

In another aspect, the present disclosure further provides a sensing apparatus. The sensing apparatus comprises the first sensing unit comprising the one or more phase sensors configured to measure values of phase current through each of the one or more phase conductors and the neutral sensor configured to measure values of neutral current through the at least one neutral conductor. The sensing apparatus further comprises the second sensing unit comprising one or more phase sensors configured to measure values of phase current through each of the one or more phase conductors of the plurality of distribution lines and the second neutral sensor configured to measure values of ground current through the at least one ground conductor.

The present disclosure also relates to the apparatus as described above. Various embodiments and variants disclosed above, with respect to the aforementioned first aspect, apply mutatis mutandis to the apparatus. Beneficially, the sensing apparatus removes the potential errors in measurements of phase currents arising from remnant currents in the at least one neutral conductor and/or the at least one ground conductor and thereby enables the system (or other existing systems) to manage effectively and accurately the electric grid in an efficient and cost-effective manner.

### DETAILED DESCRIPTION OF DRAWINGS

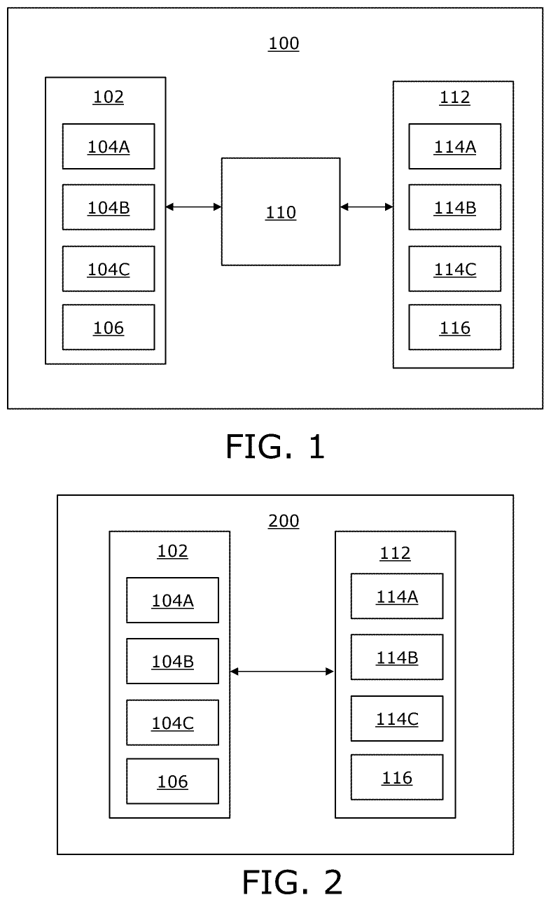

Referring to FIG. 1, illustrated is a block diagram of a system 100 for management of an electric grid, in accordance with one or more embodiments of the present disclosure. The system, in FIG. 1, is connected to an electric grid which comprises a plurality of distribution lines, i.e., feeder lines, through which the electricity is transferred, wherein each of the plurality of distribution lines comprises one or more phase conductors, at least one ground conductor and/or at least one neutral conductor. As shown, the system 100 comprises a first sensing unit 102 and a second sensing unit 112. Herein, the first sensing unit 102 comprises one or more phase sensors 104A, 104B, 104C (i.e., three-phase system) configured to measure values of phase current through each of the one or more phase conductors and a neutral sensor 106 configured to measure values of neutral current through the at least one neutral conductor. The second sensing unit 112 comprises three phase sensors 114A, 114B, 114C configured to measure values of phase current through each of the one or more phase conductors and a second neutral sensor 116 configured to measure values of ground current through the at least one ground conductor. Further, the system 100 comprises a processing unit 110 operatively coupled with the first sensing unit 102 and the second sensing unit 112. Herein, the processing unit 110 is configured to receive information about measurements of currents from the first sensing unit 102 and the second sensing unit 112, determine changes in values of current through each of the plurality of distribution lines and the at least one neutral conductor via the first sensing unit 102 and/or changes in values of current through each of the plurality of distribution lines and the at least one ground conductor via the second sensing unit 112, and detect a transient fault event and location thereof in the electric grid based on the determined changes in values of current from corresponding second sensing unit 112 or the first sensing unit 102. The present embodiment of the system 100 utilizes a three-phase power distribution architecture. However, it will be appreciated that the system 100 may utilize a single phase or double phase power distribution architecture without any limitations.

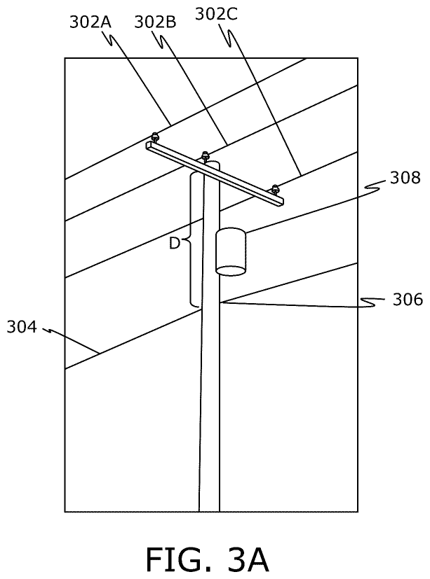

Referring to FIG. 2, illustrated is a block diagram of a sensing apparatus 200, in accordance with one or more embodiments of the present disclosure. As shown, the sensing apparatus 200 comprises the first sensing unit 102 comprising the one or more phase sensors 104A, 104B, 104C configured to measure values of phase current through each of the one or more phase conductors and the neutral sensor 106 configured to measure values of neutral current through the at least one neutral conductor. The sensing apparatus 200 further comprises the second sensing unit 112 comprising the one or more phase sensors 114A, 114B, 114C configured to measure values of phase current through each of the one or more phase conductors and the second neutral sensor 116 configured to measure values of ground current through the at least one ground conductor.

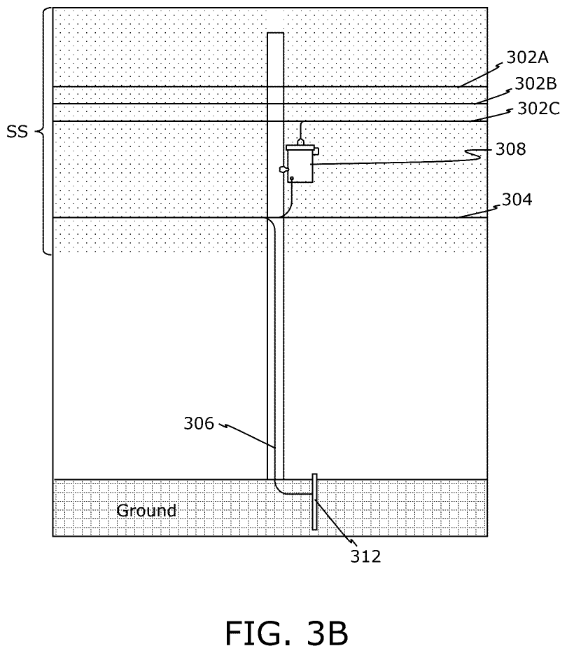

Referring to FIGS. 3A and 3B, illustrated are exemplary depictions of electric pole(s) implemented for carrying a plurality of distribution lines, at least one neutral conductor and at least one ground conductor of the electric grid, in accordance with one or more embodiments of the present disclosure. The illustrated figures depict a conventional North American utility pole showing hardware for a residential 240/120 V split-phase service drop. Referring specifically to FIG. 3A, illustrated is a diagrammatic illustration of an exemplary electric pole. As shown, the electric pole is configured to carry a plurality of distribution lines having one or more phase conductors 302A, 302B, 302C i.e., a three-phase distribution, on top of the electrical poles for safely distributing electricity to an end-user, wherein the electric pole further comprises at least one neutral conductor 304 i.e., a multi-grounded neutral conductor acting as a return path for the electrical grid and at least one ground conductor 306 acting as a low-resistance path for grounding fault currents. Notably, the at least one neutral conductor 304 is arranged at a distance ‘D’ from the one or more phase conductors 302A, 302B, 302C, wherein the vertical space formed therebetween provides a supply space for installation of electronic devices and/or equipment, for example, transformer, lightning arrestors, fuses, etc. Further, as shown, in the supply space, the electric pole comprises a transformer 308, i.e., a single-phase distribution transformer, configured for enabling power distribution within the electric grid. Referring specifically to FIG. 3B, illustrated is a schematic illustration of the exemplary electric pole of FIG. 3A. As shown, the electric pole is divided into different zones or spaces for enabling distinction of different sections of operational zones in the electric pole. In particular, as shown in FIG. 3B, the top space of the electric pole represents a supply space denoted by ‘SS’ and depicted by a dotted pattern. Further shown in FIG. 3B is the at least one ground conductor 306 running vertically downwards from the transformer 308 towards a ground rod 312 configured for absorption of ground faults.

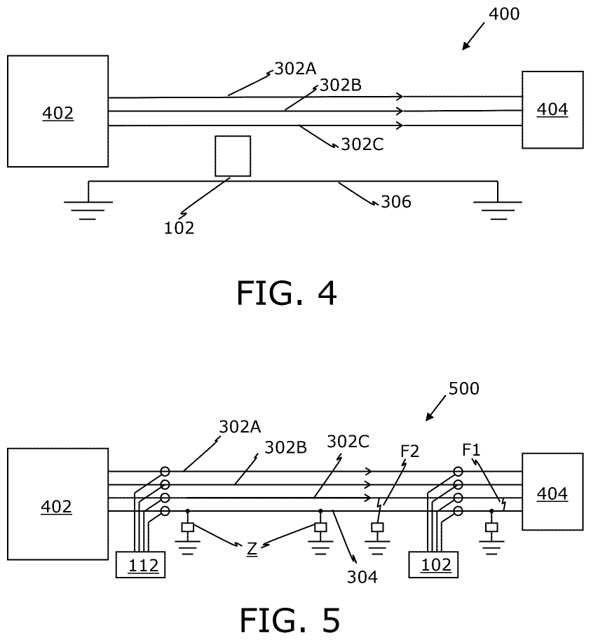

Referring to FIG. 4, illustrated is a simplified electric grid 400 depicting working of the first sensing unit 102, in accordance with one or more embodiments of the present disclosure. Herein, the illustration is associated with electric poles having at least one grounded neutral conductor 306. The power is being distributed from a source 402, for example, a transformer or power station, to a given load 404, for example, an end-user or consumer, via the one or more phase conductors 302A, 302B, 302C. Herein, in the system 100, to manage the electric grid 400, the first sensing unit 102 is installed at a distance from the plurality of distribution lines 302A, 302B, 302C in the supply space (not shown in FIG. 4) for monitoring current flow therein. However, it will be appreciated that the first sensing unit 102 may be installed at any other location on or near the electric poles. The installation locations of the first sensing unit are therefore not limited to the supply space only. Typically, the first sensing unit 102 is configured to measure the phase currents through each of the one or more phase conductors 302A, 302B, 302C and the neutral current through the at least one neutral conductor 304 (not shown in FIG. 4). Typically, in cases wherein if an electric pole has a ground wire or neutral wire in addition to the one or more phase conductors, then determining the values of currents using only three magnetic sensors is not possible since the neutral or ground wire also carries current. Thus, implementation of a proximity sensor, i.e., the neutral sensor or second neutral sensor, to measure the neutral current or ground current, respectively, allows the processing unit to accurately determine the values of current through each of the one or more phase conductors 302A, 302B, 302C, the at least one neutral conductor 304 or and the at least one ground conductor 306. Further, upon determining the location of the associated wire in space, the phase currents may be accurately determined with the three phase sensors of the first sensing unit 102.

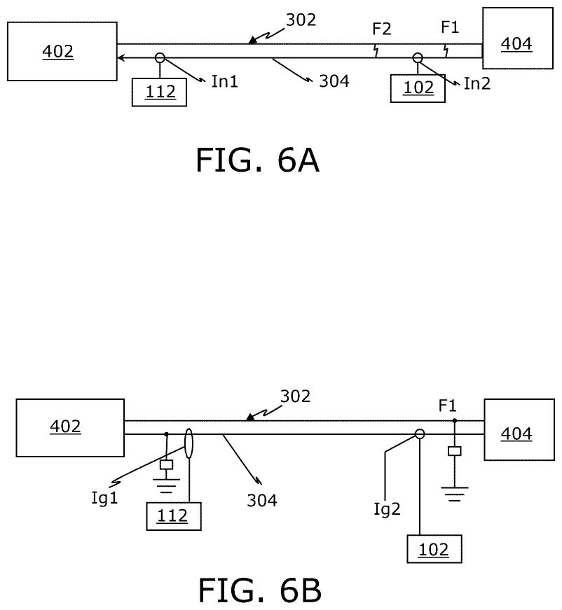

Referring to FIG. 5, illustrated is a schematic diagram of a portion of an electric grid 500 managed via the system 100, in accordance with one or more embodiments of the present disclosure. As shown, in the electric grid 500, the source 402 (for example, substation or transformer) is configured for distributing power towards the load 404, wherein the first sensing unit 102 and the second sensing unit 112 may be installed along the one or more phase conductors 302A, 302B, 302C for enabling monitoring and management of the electric grid 500 via the system 100. Herein, along the one or more phase conductors 302A, 302B, 302C, there are multiple electric poles having further defined impedances‘Z’ i.e., each of the electric pole have an impedance of Z. Conventionally, the current(s) flowing in the at least one neutral conductor 304, or the at least one ground conductor 306, cause errors in measurement of phase currents in the one or more phase conductors 302A, 302B, 302C, and thus, the first sensing unit 102 and the second sensing unit 112 enable the system to measure the ground current or neutral current for enabling accurate measurement of the phase currents and elimination any potential errors due to the aforementioned ground or neutral currents. Herein, the second sensing unit 112 is connected to the at least one ground conductor 306 (not shown) of the source 402 and the first sensing unit 102 is installed along the one or more phase conductors 302A, 302B, 302C and the at least one neutral conductor 304 such as, along electric poles as explained earlier. It will be appreciated that only a single first sensing unit 102 is illustrated in FIG. 5 for simplification. However, any number of such first sensing units 102 may be installed at each, or several electric poles (or another component within the electric grid) without any limitations.

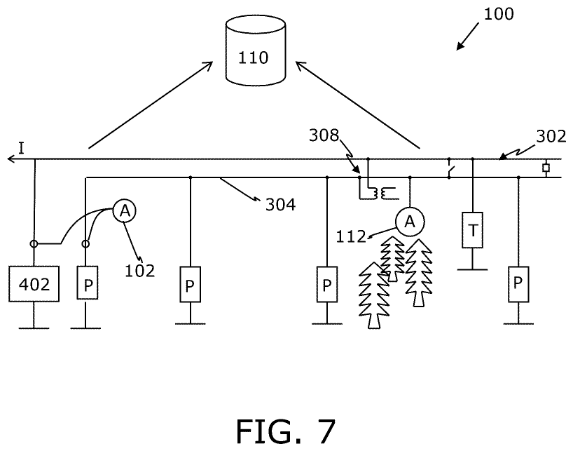

Referring to FIGS. 6A and 6B, illustrated are exemplary scenarios of the implementation of the first sensing unit 102 and the second sensing unit 112, respectively, in the electric grid 500 of FIG. 5, in accordance with one or more embodiments of the present disclosure. Herein, the fault current path approximation of faults F1 and F2 occurring at different distances from the source 402 are identified via the system 100. As shown, in FIG. 6A, the first sensing unit 102 is installed to measure the values of neutral current ‘In1’ and ‘In2’ flowing through the at least one neutral conductor 304 (of the electric grid 500); whereas, in FIG. 6B, the second sensing unit 112 is installed to measure the values of ground current “Ig1” and “Ig2” flowing through the at least one ground conductor 306 (of the electric grid 500).

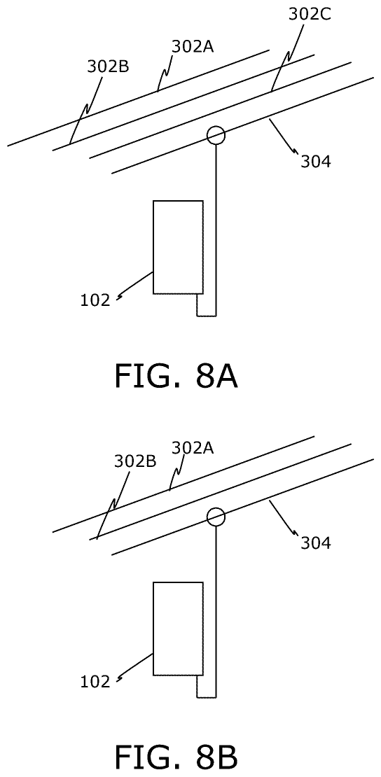

Referring to FIG. 7, illustrated is an exemplary working environment of the system 100, in accordance with one or more embodiments of the present disclosure. Herein, the one or more phase conductors 302 (simply depicted by a singular line) is a 3-phase line with phases L1, L2, L3 having at least one neutral conductor 304. Initially, power is transmitted via the one or more phase conductors 302 from the source 402. Along the lines there are further defined impedances as Zg, Zp and Zt, wherein Zp is impedance of electric pole P, and Zt is impedance of tree T (or any other object). Herein, the first sensing unit 102 may be arranged in one or more of the electric pole P and wherein, the second sensing unit 112 is arranged e.g., in or near a substation or source 402. The sensed data, i.e., measured information, the measured values, from the first sensing unit 102 and the second sensing unit 112 is thereby transmitted to the processing unit 110 operatively coupled therewith for further processing. Consequently, based on the detected changes in values of current, the processing unit 110 and/or the system 100 to identify and locate any fault events or errors in the electric grid. Beneficially, such an arrangement of the first sensing unit 102 and the second sensing unit 112 enables the system 100 to eliminate measurement errors in order to improve accuracy of phase current measurements as per embodiments of the present disclosure.

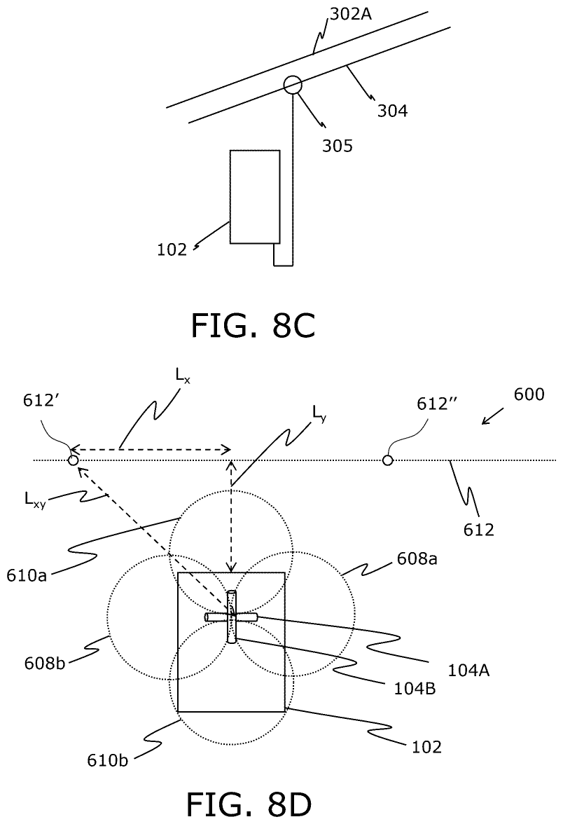

Referring to FIGS. 8A to 8C, illustrated are schematic diagrams depicting implementation of the first sensing unit 102 in differently wired electrical grids having at least one neutral conductor 304, in accordance with one or more embodiments of the present disclosure. As shown, in FIG. 8A, the first sensing unit 102 is applied along the at least one neutral conductor 304 in an exemplary four-wired (or three-phase) electrical grid having three phase conductors 302A, 302B, 302C and the at least one neutral conductor 304. Further, as shown in FIG. 8B, the first sensing unit 102 is applied along the at least one neutral conductor 304 in an exemplary three-wired (or two-phase) electrical grid having two phase conductors 302A, 302B and the at least one neutral conductor 304. Furthermore, as shown in FIG. 8C, the first sensing unit 102 is applied along the at least one neutral conductor 304 in an exemplary two-wired (or two-phase) electrical grid having one phase conductor 302A and the at least one neutral conductor 304, and a neutral sensor 305.

FIG. 8D is an exemplary illustration of a measurement configuration of a system 100, in accordance with an embodiment of the present disclosure. FIG. 8D illustrates a first sensing unit of the system arranged at a distance from the overhead line 612 wherein the two phase sensors are configured to measure values of magnetic field densities generated due to the phase current flowing through each of the two phase conductors 612′ and 612″ of an overhead line 612. The first sensing unit further comprises a neutral sensor configured to measure value of neutral current through the at least one neutral conductor (the neutral sensor and the neutral conductor are shown in FIG. 8B). The neutral sensor may also be configured to measure the value of ground current through the at least one ground conductor. The system 100 further comprises a second sensing unit (not shown in FIG. 8D) wherein the one or more phase sensors is/are configured to measure values of magnetic field densities generated due to the phase current flowing through each of the one or more phase conductors, a second neutral sensor which is configured to measure value of neutral current through the at least one neutral conductor, and/or to measure value of ground current through the at least one ground conductor.

Referring to FIG. 8D, the system 100 comprises two phase sensors, i.e., a first phase sensor 104A and a second phase sensor device 104B. The second phase sensor 104B is arranged in an angled position relative to the first phase sensor so that it overlaps with the first phase sensor 104A, and the sensors 104A and 104B have a distance between them. Herein, at least a portion of the first sensing unit 102 is arranged on an electrical pole of an electrical utility grid. The first phase sensor 104A and the second phase sensor 104B, in operation, sense (measure) magnetic field densities with directional gain illustrated as 608a, 608b, 610a, 610b to an electrical overhead line 612 of an electrical utility grid to generate sensor data, i.e., sensed (measured) values of magnetic field densities. The second phase sensor 104B senses magnetic field density in close proximity areas 608a, and 608b, and the first phase sensor 104A senses magnetic field density in close proximity areas 610a and 610b. Depending on distances Lx, Ly, Lxy between the electrical overhead line 612 and the phase sensors 104A, 104B and with directional gain illustrated as 608a, 608b, 610a, 610b, directional gains of the phase sensors 104A, 104B are calculated for generating the sensor data.

It should be understood that in the sensing (measuring) of magnetic field densities any one of the phase sensors 104A, 104B, 104C, 114A, 114B, 114C will measure the total magnetic field induced by all the phase and neutral and ground conductors, at the location and direction of the sensor. In addition, the sensing of the magnetic field density in this implementation does not require the Rogowski coil to be wound around the phase conductor/phase conductors, but the sensing of the magnetic field density can be realized with each sensing unit from a distance from the phase conductors, without the Rogowski coil.

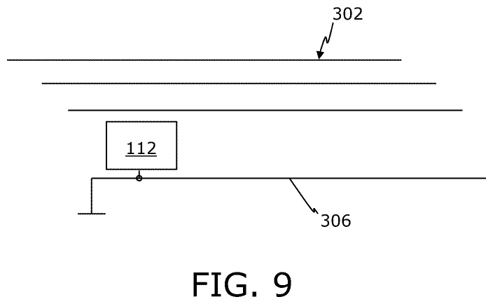

Referring to FIG. 9, illustrated is a schematic diagram depicting implementation of the second sensing unit 112 in an exemplary feeder line of a three-phase ground-isolated, compensated (Petersen coil), or impedance grounded grid with at least one ground conductor 306, in accordance with one or more embodiments of the present disclosure. As shown, the second sensing unit 112 is applied along the at least one ground conductor 306 in an exemplary four-wired electrical grid having the at least one ground conductor 306.

Modifications to embodiments of the present disclosure described in the foregoing are possible without departing from the scope of the present disclosure as defined by the accompanying claims. Expressions such as “including”, “comprising”, “incorporating”, “have”, “is” used to describe and claim the present disclosure are intended to be construed in a non-exclusive manner, namely allowing for items, components or elements not explicitly described also to be present. Reference to the singular is also to be construed to relate to the plural.

1. A system for management of an electric grid, the electric grid comprising a plurality of distribution lines having one or more phase conductors, at least one ground conductor and/or at least one neutral conductor, the system comprising:
a first sensing unit, wherein in the first sensing unit, each of one or more phase sensors is a magnetic sensor and a first neutral sensor is a Rogowski coil sensor, or a current transformer,
one or more phase sensors configured to measure values of phase current through each of the one or more phase conductors; and
a neutral sensor configured to measure value of neutral current through the at least one neutral conductor;
a second sensing unit, wherein in the second sensing unit, each of the one or more phase sensors is a magnetic sensor and a second neutral sensor is a Rogowski coil sensor, or a current transformer, comprising:
one or more phase sensors configured to measure values of phase current through each of the one or more phase conductors; and
a second neutral sensor configured to measure value of ground current through the at least one ground conductor; and
a processing unit operatively coupled with the first sensing unit and the second sensing unit; the processing unit configured to: —receive information about measurements of currents from the first sensing unit and the second sensing unit;
determine changes in values of current measured through each of the one or more phase conductors and the value of neutral current measured through the at least one neutral conductor via the first sensing unit, and changes in values of current measured through each of the one or more phase conductors and the value of ground current measured through the at least one ground conductor via the second sensing unit;
detect a fault event in the electric grid based on comparison of the determined changes in values of currents from the first sensing unit and the second sensing unit; and
localize a fault event in the electric grid using transient current signals and changes in values of currents determined by the first and second sensing units,
wherein, when determining the values of currents flowing through the one or more phase conductors, the processing unit or the first or second sensing unit is configured to subtract from the values of magnetic field densities measured for the one or more phase conductors, the values of magnetic field densities measured for the neutral conductor and/or the ground conductor to reduce disturbances during measurement of the magnetic fields of the phase conductors.

2. A system according to claim 1, wherein the processing unit is configured to:
detect a fault event location in the electric grid based on the comparison of the determined changes in values of currents from the first sensing unit and the second sensing unit;
analyze transient current signals and changes in values of currents to identify the faulted conductor or phase; and
determine the fault location using the received current measurements from the first sensing unit and the second sensing unit

3. A system according to claim 1, wherein in the second sensing unit, each of the one or more phase sensors and the second neutral sensor is one of a Rogowski coil sensor, a current transformer, or a magnetic sensor.

4. (canceled)

5. A system according to claim 1, wherein in the first sensing unit, each of the one or more phase sensors and the first neutral sensor is one of a Rogowski coil sensor, a current transformer, or a magnetic sensor.

6. (canceled)

7. A system according to claim 1, wherein the first sensing unit and the second sensing unit are arranged at a distance from each other in separate enclosures.

8. A system according to claim 1, wherein the processing unit is configured to process the information about measurements of currents from the first sensing unit and the second sensing unit, and wherein the information about measurements of currents comprises values of at least one of: phase currents through each of the one or more phase conductors, ground current through the at least one ground conductor, or neutral current in the at least one neutral conductor, to determine changes in values of currents measured through each of the one or more phase conductors, the at least one neutral conductor, or the at least one ground conductor.

9. A system according to claim 1, wherein each one of the one or more phase sensors in the first sensing unit are connected to one of the one or more phase conductors in the plurality of distribution lines of the electric grid.

10. A system according to claim 1, wherein, the one or more phase sensors is/are configured to measure values of magnetic field densities generated due to the phase current flowing through each of the one or more phase conductors; and the neutral sensor and/or the second neutral sensor is/are configured to measure values of magnetic field densities generated due to the neutral current flowing through the at least one neutral conductor and/or due to the ground current flowing through the at least one ground conductor to generate sensor data for a magnetic field in each dimension based on the sensed presence and magnitude of the magnetic field, to determine the values of current flowing through the one or more phase conductors.

11. A system according to claim 1, wherein the processing unit is configured to:
receive sensor data from the first sensing unit and/or the second sensing unit; and
process the sensor data to generate the measurement data determine values of magnetic field densities produced by electrical current in the plurality of distribution lines and determine the values of currents flowing through the one or more phase conductors, based on the values of the magnetic field densities received, and directivity and orientation of the one or more phase sensors and distance and position of the one or more phase conductors from the one or more phase sensors.

12-24. (canceled)

25. A system according to claim 1, wherein the processing unit is configured to: determine the type of fault event based on a comparative analysis of changes in values of phase current, neutral current, and ground current, distinguishing between transient faults, ground faults, and neutral current imbalances.

26. A system according to claim 1, comprising at least one of: an anti-disturbance filter, an amplifier, a digitizer, an optical transmitter and/or a radio transmitter, to reduce disturbances during measurement of the magnetic fields and/or to improve voltage isolation from high-voltage components.

27. A system according to claim 1, wherein the system is configured to remove the errors in measurements of phase currents arising from remnant currents in the at least one neutral conductor and/or the at least one ground conductor.

28. A sensing apparatus comprising:
a first sensing unit, wherein in the first sensing unit, each of one or more phase sensors is a magnetic sensor and a first neutral sensor is a Rogowski coil sensor, or a current transformer comprising:
one or more phase sensors configured to measure values of phase current through each of the one or more phase conductors; and
a neutral sensor configured to measure value of neutral current through the at least one neutral conductor; and
a second sensing unit, wherein in the second sensing unit, each of the one or more phase sensors is a magnetic sensor and a second neutral sensor is a Rogowski coil sensor, or a current transformer, comprising:
one or more phase sensors configured to measure values of phase current through each of the one or more phase conductors; and
a second neutral sensor configured to measure values of ground current through the at least one ground conductor.

29. A sensing apparatus according to claim 28, wherein, the one or more phase sensors is/are configured to measure values of magnetic field densities generated due to the phase current flowing through each of the one or more phase conductors; and the neutral sensor and/or the second neutral sensor is/are configured to measure values of magnetic field densities generated due to the neutral current flowing through the at least one neutral conductor and/or due to the ground current flowing through the at least one ground conductor to generate sensor data for a magnetic field in each dimension based on the sensed presence and magnitude of the magnetic field, in order to determine the values of current flowing through the one or more phase conductors.

30. A sensing apparatus according to claim 28, wherein the sensing apparatus is configured to remove the errors in measurements of phase currents arising from remnant currents in the at least one neutral conductor and/or the at least one ground conductor.

31. A method for management of an electric grid, comprising:
measuring, by using a first sensing unit, wherein in the first sensing unit, each of one or more phase sensors is a magnetic sensor and a first neutral sensor is a Rogowski coil sensor, or a current transformer, value(s) of phase current through each of the one or more phase conductors; and value of neutral current through the at least one neutral conductor;
measuring, by using a second sensing unit, wherein in the second sensing unit, each of the one or more phase sensors is a magnetic sensor and a second neutral sensor is a Rogowski coil sensor, or a current transformer, value(s) of phase current through each of the one or more phase conductors; and value(s) of ground current through the at least one ground conductor;
determining changes in values of current measured through each of the one or more phase conductors and the value of neutral current measured through the at least one neutral conductor via the first sensing unit and changes in values of current measured through each of the one or more phase conductors and the value of ground current measured through the at least one ground conductor via the second sensing unit; and
detecting a fault event in the electric grid based on comparison of the determined changes in values of currents from the first sensing unit and the second sensing unit,
wherein, when determining the values of currents flowing through the one or more phase conductors, subtracting, by the processing unit or by the first or second sensing unit, from the values of magnetic field densities measured for the one or more phase conductors, the values of magnetic field densities measured for the neutral conductor and/or the ground conductor to reduce disturbances during measurement of the magnetic fields.

32. A method according to claim 31, wherein detecting a fault event location in the electric grid is based on the comparison of the determined changes in values of currents from the first sensing unit and the second sensing unit, wherein said comparison includes comparing the determined changes in values of currents from the neutral sensor of the first sensing unit and the second neutral sensor of the second sensing unit.

33. A method according to claim 31, comprising:
measuring, by the one or more phase sensors, values of magnetic field densities generated due to the phase current flowing through each of the one or more phase conductors; and
measuring, by the neutral sensor and/or the second neutral sensor, the values of magnetic field densities generated due to the neutral current flowing through the at least one neutral conductor and/or due to the ground current flowing through the at least one ground conductor, to generate sensor data for a magnetic field in each dimension based on the sensed presence and magnitude of the magnetic field, to determine the values of current flowing through the one or more phase conductors.

33. A method according to claim 31, wherein:
receiving, by the processing unit, sensor data from the first sensing unit and/or the second sensing unit; and
process the sensor data to determine, by the processing unit, values of magnetic field densities produced by electrical current in the plurality of distribution lines and determining the values of currents flowing through the one or more phase conductors, based on the values of the magnetic field densities received, and directivity and orientation of the one or more phase sensors and distance and position of the one or more phase conductors from the one or more phase sensors.

34. A method according to claim 31, wherein:
removing the errors in measurements of phase currents arising from remnant currents in the at least one neutral conductor and/or the at least one ground conductor.
